(19) United States
(12) Patent Application Publication
(10) Pub. No.: US 2006/0279980 A1
(43) Pub. Date: Dec. 14, 2006

(54) Magnetic storage cell and magnetic memory device

(75) Inventors: Susumu Haratani, Tokyo (JP); Keiji Koga, Tokyo (JP); Joichiro Ezaki, Tokyo (JP)

Correspondence Address: GREENBLUM & BERNSTEIN, P.L.C., 1950 ROLAND CLARKE PLACE, RESTON, VA, 20191, US

(73) Assignee: TDK Corporation, Tokyo (JP)

(21) Appl. No.: 10/568,808

(22) PCT Filed: Aug. 18, 2004
(86) PCT No.: PCT/JP04/11832

§ 371 Date: Feb. 21, 2006

(30) Foreign Application Priority Data
Aug. 21, 2003 (JP) 2003-208165

(51) Int. Cl. G11C 11/00

(52) U.S. Cl. 365/158

(57) ABSTRACT

To provide a magnetic memory cell that is capable of efficiently changing the magnetization directions of magneto-sensitive layers. A magnetic memory cell comprises an annular magnetic layer 4a through which extends a write bit line 5a that generates a magnetic field, and a TMR film S20a configured so as to include: a first magneto-sensitive layer 14a, a magnetization direction of which is changed by the magnetic field in the annular magnetic layer 4a; and a magnetoresistive effect revealing body 20a disposed on a surface of the first magneto-sensitive layer 14a so that an electric current flows in a direction perpendicular to a laminating surface of the laminate, and the first magneto-sensitive layer 14a has a thickness thereof set in a range of not less than 0.5 nm to not more than 40 nm.

### TECHNICAL FIELD

The present invention relates to a magnetic memory cell including a magnetoresistive effect revealing body, and a magnetic memory device including a plurality of magnetic memory cells such that information can be recorded therein and read out therefrom.

### BACKGROUND ART

As the magnetic memory device using magnetic memory cells of the above-mentioned kind, a magnetic random access memory (hereinafter also referred to as “MRAM”; Magnetic Random Access Memory) is known. This MRAM stores information by making use of a combination of magnetization directions (parallel or antiparallel) of two ferromagnetic bodies contained in the magnetoresistive effect element. On the other hand, the reading of stored information is carried out by detecting a change in the resistance value (i.e., a change in electric current or voltage) between different resistance values of the magnetoresistive effect element which varies between when the magnetization directions of the two ferromagnetic bodies are parallel and when the same are antiparallel.

The MRAMs having been put into practical use today make use of giant magnetoresistive (GMR: Giant Magneto-Resistive) effect. As MRAMs using GMR elements which provide the GMR effect, one disclosed in U.S. Pat. No. 5,343,422 is known. In this case, the GMR effect means a phenomenon where the resistance value of an element is minimum when the magnetization directions of two magnetic layers parallel to each other along the axis of easy magnetization are parallel to each other, and is maximum when the same are antiparallel to each other. As the MRAMs using the GMR element, there are a coercive force difference type (pseudo spin valve type) and a switching bias type (spin valve type). The MRAM of the coercive force difference type is configured such that the GMR element thereof has two ferromagnetic layers and a non-magnetic layer sandwiched therebetween, and writes in and reads out information by making use of the difference in coercive force between the two ferromagnetic layers. Here, for example, when the GMR element has a composition of “nickel-iron alloy (NiFe)/copper (Cu)/cobalt (Co)”, the ratio of change in resistance has a small value of around 6 to 8%. On the other hand, the MRAM of the switching bias type is configured such that the GMR element has a fixed layer whose magnetization direction is fixed by exchange-coupling with an antiferromagnetic layer, a magneto-sensitive layer, a magnetization direction of which is changed by an external magnetic field, and a non-magnetic layer sandwiched between them, and writes in and reads out information by making use of the difference in magnetization direction between the fixed layer and the magneto-sensitive layer. For example, when the GMR element has a composition of “platinum manganese (PtMn)/cobalt-iron (CoFe)/copper (Cu)/CoFe”, the ratio of change in resistance exhibits a value of around 10%, which is larger than that of the coercive force difference type. However, it is insufficient to attain a further higher recording speed or access speed.

To solve these problems, there has been proposed an MRAM that uses as a magnetic memory cell a magnetoresistive effect element (also referred to as “storage element” in the present specification) 120 constructed as shown in FIG. 14 which utilizes a tunneling magnetoresistive effect (hereinafter also referred to as “the TMR effect”). This MRAM is comprised of a plurality of bit lines 105 arranged parallel to each other, a plurality of write word lines 106 arranged parallel to each other and orthogonal to the bit lines 105, a plurality of read word lines 112 arranged along the write word lines 106, and a plurality of storage elements 120 arranged in a manner sandwiched between orthogonally-crossing portions (intersecting portions) of the bit lines 105 and the write word lines 106. In this case, as shown in FIG. 14, the storage element 120 includes a first magnetic layer 102, a tunnel barrier layer 103, and a magneto-sensitive layer 104 as a second magnetic layer, and these layers 102, 103, and 104 are deposited in the mentioned order.

It should be noted that the TMR effect is an effect in which the tunnel current flowing through the tunnel barrier layer 103 varies with a relative angle between magnetization directions of the first magnetic layer 102 and the magneto-sensitive layer 104 as two ferromagnetic layers sandwiching the tunnel barrier layer 103 as a very thin insulating layer (non-magnetic conductive layer). In this case, the resistance value becomes minimum when the magnetization directions of the first magnetic layer 102 and the magneto-sensitive layer 104 are parallel to each other, and becomes maximum when the magnetization directions are antiparallel to each other. Further, in the MRAM making use of the TMR effect, when the storage element 120 has a composition of “CoFe/aluminum oxide/CoFe”, for example, the rate of change in resistance is as high as around 40%, and the resistance values are also high. This makes it easy to achieve matching when the MRAM is combined with a semiconductor device, such as a MOSFET. Therefore, compared with MRAMs having a GMR element, a higher output can be easily obtained, from which it can be expected that the storage capacity and the access speed are improved. In the MRAM making use of the TMR effect, information is stored by changing the magnetization direction of the magneto-sensitive layer 104 of the storage element 120 to a predetermined direction using the electromagnetic field generated by passing electric currents through a bit line 105 and a write word line 106 appearing in FIG. 14. On the other hand, in reading out the stored information, the change in resistance of the storage element 120 is detected by passing an electric current perpendicular to the tunnel barrier layer 103 through the storage element 120 via the bit line 105 and the read word line 112. It should be noted that MRAMs using the TMR effect are disclosed in U.S. Pat. No. 5,629,922, Japanese Laid-Open Patent Publication (Kokai) No. H09-91949, and so forth.

Patent Literature 1: U.S. Pat. No. 5,343,422

Patent Literature 2: U.S. Pat. No. 5,629,922

Patent Literature 3: Japanese Laid-Open Patent Publication No. H09-91949

### DISCLOSURE OF THE INVENTION

### Problem to Solved by the Invention

The inventors studied the conventional MRAM using the storage element making use of the TMR effect described above, and as a result, found out the following problems: In the MRAM, the magnetization direction of the magneto-sensitive layer 104 is changed by an induction field (i.e., electromagnetic field) produced by electric currents flowing through the bit line 105 and the write word line 106 arranged orthogonal to each other, whereby information is stored in each storage element 120 as a memory cell. However, due to the fact that the electromagnetic field is an open field (not magnetically confined within a specific area), there is much magnetic flux leakage, and therefore the MRAM has the problem of low writing efficiency. At the same time, there is a risk of the leakage magnetic flux having adverse influences on adjacent storage elements 120.

Further, to attain an even higher density of the MRAM by higher integration of storage elements 120, it is necessary to make the storage elements 120 very small. On the other hand, when the storage elements are made very small, due to an increase in the ratio of thickness to width along the laminating surface (aspect ratio=thickness/width along the laminating surface), a demagnetizing field increases, and therefore the magnetic field strength required for changing the magnetization direction of the magneto-sensitive layer increases. Further, as described hereinabove, the electromagnetic field produced by electric currents flowing through the bit line 105 and the write word line 106 is open, which lowers the writing efficiency. These bring about the problem that it is necessary to cause larger write currents to flow through this MRAM in recording information by changing the magnetization direction of the magneto-sensitive layer.

As a solution to this problem, the present inventors developed a magnetic memory cell 1 having a construction as shown in FIGS. 3 and 4(a). This magnetic memory cell (hereinafter also referred to as “memory cell”) includes a pair of storage elements 1a and 1b. Here, the storage elements 1a and 1b each comprise annular magnetic layers 4a and 4b through each of which extends at least one conductor (a write bit line 5a and a write word line 6, and a write bit line 5b and a write word line 6), and TMR films (laminates) S20a and S20b that are respectively configured to include: first magneto-sensitive layers 14a and 14b, magnetization directions of which are changed by the magnetic fields in the annular magnetic layers 4a and 4b; and magnetoresistive effect revealing bodies 20a and 20b disposed on the surfaces of the first magneto-sensitive layers 14a and 14b so that electric currents flow in directions perpendicular to the laminating surface of the laminate. In this case, the TMR films S20 AND S20b are each comprised of a plurality of layers including the second magnetic layers (second magneto-sensitive layers) 8a and 8b formed as a laminate. The annular magnetic layers 4a and 4b are arranged such that the direction along the laminating surfaces of the TMR films S20a and S20b (direction perpendicular to the sheet surface of the figure) is an axial direction. It should be noted that the axes of the annular magnetic layers 4a and 4b are respectively designated by F and G in FIG. 4(a). Further, the memory cell 1 is configured such that the annular magnetic layers 4a and 4b are configured to be arranged side by side with the respective axial directions mentioned above coincident with each other and share a predetermined portion (shared portion 34) sandwiched between the respective pairs of conductors (the write bit line 5a and the write word line 6, and the write bit line 5b and the write word line 6), which extend through the associated annular magnetic layers 4a and 4b, respectively.

By employing this construction, the magnetic fluxes generated around the write bit lines 5a and 5b and the write word lines 6 by electric currents flowing through both the write bit lines 5a and 5b and the write word lines 6 can be confined within the closed magnetic circuits formed by the respective annular magnetic layers 4a and 4b, and hence the generation of the magnetic flux leakage can be reduced, which makes it possible to reduce the adverse influences on the adjacent memory cells and enhance the writing efficiency. Further, since the memory cell 1 is configured such that it comprises a pair of storage elements 1a and 1b respectively having the pair of TMR films S20a and S20b and the pair of annular magnetic layers 4a and 4b through which extend the write bit lines 5a (5b) and the write word lines 6, and that the pair of storage elements 1a and 1b share a portion (shared portion 34) of the annular magnetic layers 4a and 4b, compared with a memory cell in which the storage elements are provided separately from each other without sharing a portion of the annular magnetic layers, the magnetic flux density in the shared portion 34 of the annular magnetic layers 4a and 4b can be increased. As a result, the strength of circulating magnetic fields 16a and 16b (see FIG. 4(a)) in the respective annular magnetic layers 4a and 4b can be increased. Therefore, combined with little generation of the magnetic flux leakage, it is possible to execute magnetization reversal of the second magnetic layers 8a and 8b with smaller write currents. Here, the term “write current” is intended to mean a current required for inverting the magnetization directions of the magneto-sensitive layers (8a and 14a, and 8b and 14b). It should be noted that even in a memory cell which comprises, for example, a storage element (e.g., the storage element 1a in FIG. 4) having one magnetoresistive effect revealing body 20a and one annular magnetic layer 4a shown in FIG. 4, and stores one bit of information by the one annular magnetic layer 4a and the one magnetoresistive effect revealing body 20a, it is possible to confine magnetic fluxes generated by electric currents flowing through both the write bit lines 5a and 5b and the write word lines 6 around the write bit lines 5a and 5b and the write word lines 6 in a closed magnetic circuit formed by the annular magnetic layer 4a, which makes it possible to largely reduce the adverse influences on the adjacent memory cells and enhance the writing efficiency. Further, this is also the case with a memory cell that stores one bit of information using three or more annular magnetic layers 4a and a magnetoresistive effect revealing body 20a provided on each of the annular magnetic layers 4a.

By the way, in the memory cell 1 configured such that the pair of annular magnetic layers 4a and 4b share a portion thereof, when inverting the magnetization directions of the magneto-sensitive layers (8a and 14a, and 8b and 14b), write currents are supplied respectively to the write bit line 5a and the write word line 6 extending through one of the annular magnetic layers 4a, and to the write bit line 5b and the write word line 6 extending through the other annular magnetic layer 4b, and therefore, combined with the difficulty in manufacturing the storage elements la and 1b such that they have completely the same construction, there is a tendency that there is an increase in the difference in electric current as calculated between the total value of write currents supplied to the storage element 1a (the write bit line 5a and the write word line 6) and the total value of electric currents supplied to the storage element 1b (the write bit line 5b and the write word line 6). In this case, there is no other choice but to supply one of the storage elements which may be supplied with a small total value of write currents with write currents having the same values as those of electric currents (large write currents) supplied to the other storage element, and hence electric currents which are unnecessarily large are supplied to the memory cell 1, which brings about a new problem of lowered writing efficiency.

To solve the problem, the present inventors made intensive studies on the memory cell 1 in order to further reduce the write currents, and found out that a predetermined relationship is established between the thickness of the first magneto-sensitive layers 14a and 14b (see FIG. 4(a)) and the current values of write currents, and that it is possible to reduce the write currents by defining the thickness of the first magneto-sensitive layers 14a and 14b based on the relationship.

The present invention has been made based on the above findings and a main object thereof is to provide a magnetic memory cell and a magnetic memory device which are capable of efficiently changing the magnetization directions of magneto-sensitive layers thereof with a small amount of electric current.

### MEANS FOR SOLVING THE PROBLEMS

The magnetic memory cell according to the present invention comprises an annular magnetic layer through which extends at least one conductor that generates a magnetic field, and a laminate configured so as to include: a first magneto-sensitive layer, a magnetization direction of which is changed by the magnetic field in the annular magnetic layer; and a magnetoresistive effect revealing body disposed on a surface of the first magneto-sensitive layer so that an electric current flows in a direction perpendicular to a laminating surface of the laminate, wherein the first magneto-sensitive layer has a thickness set in a range of not less than 0.5 nm to not more than 40 nm. As used herein, the term “magnetic field” is intended to mean a magnetic filed produced by an electric current flowing through a conductor, or a circulating magnetic field produced in an annular magnetic layer. Further, the term “annular” in the “annular magnetic layer” is intended to mean a state in which as viewed from conductors extending through an inside, surroundings of the conductors are completely integrated magnetically and electrically continuously, and a cross-section in a direction across the conductors is closed. Therefore, the annular magnetic layer permits inclusion of an insulator insofar as it is magnetically and electrically continuous. In other words, although the annular magnetic layer does not include an insulator which prevents electric current from flowing therethrough, it may include such an amount of oxide films as produced during the manufacturing process. Further, the term “magnetoresistive effect revealing body” is intended to mean a portion (or substance) where the magnetoresistive effect is revealed or appears.

Further, the magnetic memory cell according to the present invention comprises a plurality of magnetoresistive effect elements each having an annular magnetic layer through which extends at least one conductor that generates a magnetic field and a laminate configured so as to include: a first magneto-sensitive layer, a magnetization direction of which is changed by the magnetic field in the annular magnetic layer; and a magnetoresistive effect revealing body disposed on a surface of the first magneto-sensitive layer so that an electric current flows in a direction perpendicular to a laminating surface of the laminate, wherein the plurality of annular magnetic layers are configured so as to be arranged side by side such that directions of respective axes coincide with each other, and so as to share a predetermined portion of each with each other, and wherein the plurality of first magneto-sensitive layers are disposed on a same side with respect to a plane including the axes, and each have a thickness set in a range of not less than 0.5 nm to not more than 40 nm. As used herein, the term “axial direction” or “direction of an axis” is intended to mean a direction parallel to the axis of the annular magnetic layer when attention is paid to a single annular magnetic layer, in other words, a direction toward an opening of the annular magnetic layer, that is, a direction in which the conductors extend through the inside of the annular magnetic layer. Further, the term “shared” is intended to mean a state in which a pair of annular magnetic layers are electrically and magnetically continuous to each other.

In this case, the plurality of first magneto-sensitive layers should preferably be configured so as to be magnetized in respective directions antiparallel to each other by the magnetic fields. As used herein, the term “antiparallel to each other” is intended to include not only cases where a relative angle between average magnetization directions in the magnetic layers is strictly 180 degrees, but also cases where the relative angle deviates from 180 degrees by a predetermined angle due to such an extent of error as a manufacturing error or an error occurring due to incomplete uniaxialization.

Further, it is preferable that each first magneto-sensitive layer has a thickness set in a range of not less than 0.5 nm to not more than 30 nm.

Further, it is preferable that a plurality of the conductors extend through the plurality of annular magnetic layers, and the plurality of the conductors extend in parallel to each other in a region where the plurality of the conductors extend through the plurality of annular magnetic layers.

Further, it is preferable that the laminate comprises a second magneto-sensitive layer which can be magnetically exchange-coupled with the first magneto-sensitive layer.

Further, it is preferable that the laminate comprises a non-magnetic layer, a first magnetic layer with a fixed magnetization direction deposited on one surface side of the non-magnetic layer, and a second magnetic layer deposited on the other surface side of the non-magnetic layer and functioning as the second magneto-sensitive layer, and information can be detected based on the electric current flowing through the laminate. Here, the term “information” in the present invention is intended to mean binary information generally expressed as “0” and “1” in signals input to and output from magnetic memory devices, or as “High” and “Low” by current values and voltage values.

Further, it is preferable that the first magnetic layer is formed using a material having a larger coercive force than the second magnetic layer.

Further, the magnetic memory device according to the present invention comprises the magnetic memory cell described above, write lines as the plurality of the conductors, and read lines that supply the electric current to the laminate.

### EFFECT OF THE INVENTION

The magnetic memory cell and the magnetic memory device according to the present invention comprises an annular magnetic layer through which extends at least one conductor that generates a magnetic field, and a laminate configured so as to include: a first magneto-sensitive layer, a magnetization direction of which is changed by the magnetic field in the annular magnetic layer; and a magnetoresistive effect revealing body disposed on a surface of the first magneto-sensitive layer so that an electric current flows in a direction perpendicular to a laminating surface of the laminate, and the thickness of the first magneto-sensitive layer is set within a range of not less than 0.5 nm to not more than 40 nm. Therefore, it is possible to ensure a thickness of 0.5 nm or more, which enables the first magneto-sensitive layer to be stably manufactured as a magnetic film. This makes it possible to largely enhance the yield of the magnetic memory device. Further, since the thickness of the first magneto-sensitive layer is set at not more than 40 nm, a demagnetizing field due to the thickness is decreased, thereby making it possible to reduce the current value of a write current required for inverting the magnetization direction of the first magneto-sensitive layer, while ensuring the balance between the write currents flowing through the storage element to some degree, to thereby efficiently change the magnetization direction of the first magneto-sensitive layer.

The magnetic memory cell and the magnetic memory device according to the present invention comprise a plurality of storage elements each having an annular magnetic layer through which extends at least one conductor that generates a magnetic field, and a laminate configured so as to include: a first magneto-sensitive layer, a magnetization direction of which is changed by the magnetic field in the annular magnetic layer; and a magnetoresistive effect revealing body disposed on a surface of the first magneto-sensitive layer so that an electric current flows in a direction perpendicular to a laminating surface of the laminate, wherein the plurality of annular magnetic layers are configured so as to be arranged side by side such that directions of respective axes coincide with each other, and so as to share a predetermined portion of each with each other, and the thickness of the first magneto-sensitive layers is defined within a range of not less than 0.5 nm to not more than 40 nm. Therefore, it is possible to ensure a thickness of 0.5 nm or more, which enables the first magneto-sensitive layers to be stably manufactured as magnetic films. This makes it possible to largely enhance the yield of the magnetic memory device. Further, since the thickness of the first magneto-sensitive layers is set at not more than 40 nm, a demagnetizing field due to the thickness is decreased, thereby making it possible to reduce the current values of write currents flowing through the storage elements, while ensuring the balance between the write currents required for inverting the magnetization direction of the first magneto-sensitive layer to some degree, to thereby efficiently change the magnetization directions of the first magneto-sensitive layers.

Further, according to the memory cell and the magnetic memory device according to the present invention, the plurality of magneto-sensitive layers are configured so as to be magnetized in directions antiparallel to each other by magnetic fields. This makes it possible to always align the directions of the magnetic fields generated in the shared portion of the annular magnetic layers when electric currents are caused to flow through the conductors of the pair of storage elements, and therefore it is possible to reliably increase the magnetic flux density in the shared portion of the annular magnetic layers. This makes it possible to increase the strengths of the circulating magnetic fields within the annular magnetic layers, thereby making it possible to invert the magnetization directions of the first magneto-sensitive layers with smaller write currents.

Further, according to the memory cell and the magnetic memory device according to the present invention, since the thickness of the first magneto-sensitive layers is set at not more than 30 nm, the demagnetizing field due to the thickness is further decreased, thereby making it possible to further reduce the current values of write currents required for inverting the magnetization directions of the first magneto-sensitive layers, while further balancing the write currents flowing through the storage elements, to thereby efficiently change the magnetization directions of the magneto-sensitive layers.

Further, according to the memory cell and the magnetic memory device according to the present invention, a plurality of the conductors are configured to extend in parallel with each other in a region where the conductors extend through the annular magnetic layers. Therefore, compared with a construction in which a plurality of conductors cross each other, synthetic magnetic fields produced by passing electric currents through the conductors can be increased, and therefore it is possible to more efficiently invert the magnetization directions of the first magneto-sensitive layers.

Further, according to the memory cell and the magnetic memory device according to the present invention, the laminate comprises a second magneto-sensitive layer which can be magnetically exchange-coupled with the first magneto-sensitive layer. This makes it possible to select a material having a high polarizability as a material for forming the second magneto-sensitive layer, and hence it is possible to increase the rate of change in the magnetoresistance of the storage element.

Further, according to the memory cell and the magnetic memory device according to the present invention, each laminate comprises a non-magnetic layer, a first magnetic layer with a fixed magnetization direction deposited on one surface side of the non-magnetic layer, and a second magnetic layer deposited on the other surface side of the non-magnetic layer and functioning as the second magneto-sensitive layer, and information can be detected based on the electric current flowing through a pair of the laminate. This makes it possible to also use the insulating layer capable of producing the tunnel effect, as the non-magnetic layer.

Further, according to the memory cell and the magnetic memory device according to the present invention, the first magnetic layer is formed using a material having a larger coercive force than that of the second magnetic layer. This configuration makes it possible to prevent the magnetization direction of the first magnetic layer from being adversely affected by undesired magnetic fields, such as an external disturbance magnetic field.

### BRIEF DESCRIPTION OF THE DRAWINGS

FIG. 1 is a block diagram showing the whole arrangement of a magnetic memory device M according to an embodiment of the present invention.

FIG. 2 is a fragmentary plan view showing the arrangement of essential elements of a memory cell group 54 of the FIG. 1 magnetic memory device M.

FIG. 3 is a perspective view showing the arrangement of essential elements of a memory cell 1 of the FIG. 1 magnetic memory device M.

FIGS. 4(a) to 4(c) are cross-sectional views of the FIG. 2 memory cell 1, taken on line V-V of FIG. 2.

FIG. 5 is another fragmentary plan view showing the arrangement of essential elements of the memory cell group 54 of the FIG. 1 magnetic memory device M.

FIG. 6 is a cross-sectional view of the FIG. 5 memory cell 1, taken on line W-W of FIG. 5.

FIG. 7 is a circuit diagram of the magnetic memory device M.

FIG. 8 is a circuit diagram showing part of the FIG. 7 circuit.

FIG. 9 is a diagram useful in explaining the shapes of Type A to Type C of the memory cell 1 assumed when the relationship between the thickness of first magneto-sensitive layers 14a and 14b and write currents is determined by simulation.

FIG. 10 is a diagram showing the sizes of Type A to Type C in FIG. 9 on a type-by-type basis.

FIG. 11 is a characteristic diagram obtained by simulating the relationship between the thickness of first magneto-sensitive layers 14a and 14b of a memory cell 1 of Type A and write currents.

FIG. 12 is a characteristic diagram obtained by simulating the relationship between the thickness of first magneto-sensitive layers 14a and 14b of a memory cell 1 of Type B and write currents.

FIG. 13 is a characteristic diagram obtained by simulating the relationship between the thickness of first magneto-sensitive layers 14a and 14b of a memory cell 1 of Type C and write currents.

FIG. 14 is a cross-sectional view of a conventional magnetic memory cell, which mainly shows a storage element 120.

FIG. 15 is a plan view showing the arrangement of a conventional magnetic memory device.

### BEST MODE FOR CARRYING OUT THE INVENTION

Hereinafter, an embodiment of the present invention will be described in detail with reference to the drawings.

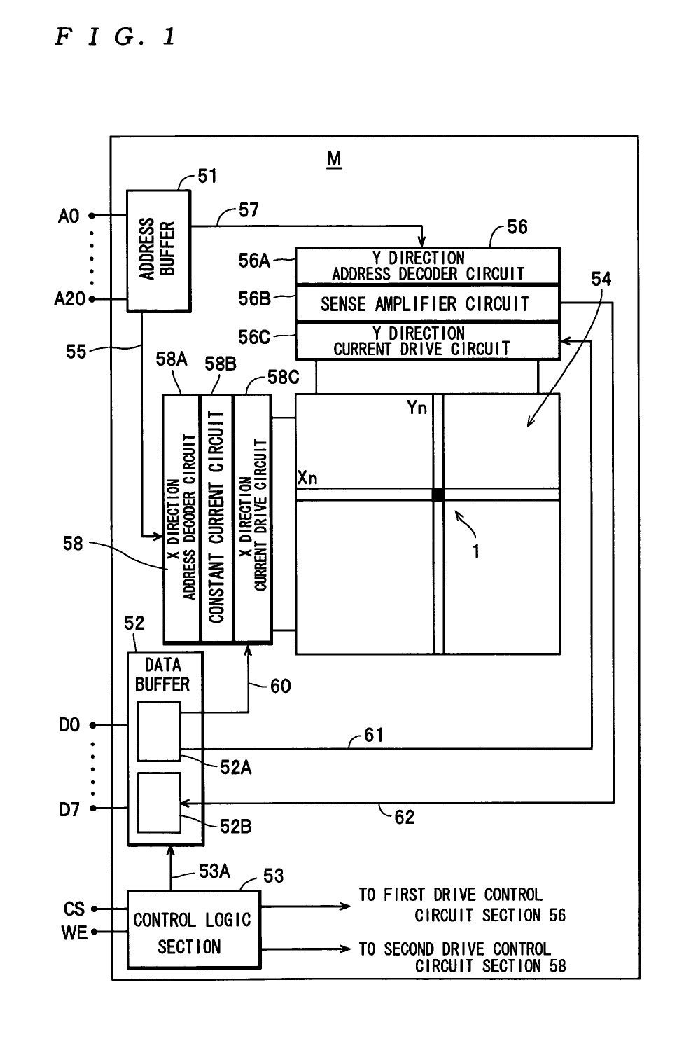

First of all, the construction of a magnetic memory device M according to the present embodiment will be described with reference to FIGS. 1 to 7.

Referring to FIG. 1, the magnetic memory device M is comprised of an address buffer 51, a data buffer 52, a control logic section 53, a memory cell group 54, a first drive control circuit section 56, and a second drive control circuit section 58.

The address buffer 51 includes external address input terminals A0 to A20, and outputs an address signal received via the external address input terminals A0 to A20 to the first drive control circuit section 56 via a Y direction address line 57, and to the second drive control circuit section 58 via an X direction address line 55.

The data buffer 52 includes external data terminals D0 to D7, an input buffer 52A, and an output buffer 52B. Further, the data buffer 52 is connected to the control logic section 53 via a control signal line 53A. In this case, the input buffer 52A is connected to the second drive control circuit section 58 via an X direction write data bus 60, and to the first drive control circuit section 56 via a Y direction write data bus 61. On the other hand, the output buffer 52B is connected to the first drive control circuit section 56 via a Y direction read data bus 62. Further, the input buffer 52A and the output buffer 52B operate according to control signals input from the control logic section 53 via the control signal line 53A.

The control logic section 53 includes an input terminal CS and an input terminal WE, and controls the operations of the data buffer 52, the first drive control circuit section 56, and the second drive control circuit section 58. More specifically, the control logic section 53 determines which of the input buffer 52A and the output buffer 52B should be made active, based on a chip select signal input via the input terminal CS and a write enable signal input via the input terminal WE, and generates a control signal for causing the input buffer 52A or the output buffer 52B to operate according to the determination, and outputs the control signal to the data buffer 52 via the control signal line 53A. Further, the control logic section 53 amplifies the chip select signal and the write enable signal to voltage levels required by the respective drive control circuit sections 56 and 58, and delivers the signals to these circuit sections.

The memory cell group 54 has a matrix structure formed by arranging a large number of memory cells 1 as magnetic memory cells at respective intersections where word lines (X direction) and bit lines (Y direction) orthogonal to each other intersect with each other. In this case, the memory cells 1 are minimum units for storing data in the magnetic memory device M, and each include a pair of storage elements (tunnel magnetoresistive effect elements). It should be noted that the memory cells will be described in detail later.

The first drive control circuit section 56 has a Y direction address decoder circuit 56A, a sense amplifier circuit 56B, and a Y direction current drive circuit 56C. On the other hand, the second drive control circuit section 58 has an X direction address decoder circuit 58A, a constant current circuit 58B, and an X direction current drive circuit 58C.

In this case, as shown in FIG. 7, the Y direction address decoder circuit 56A selects a bit decode line 71 ( . . . , 71n, 71n+1, . . . ) based on the address signal input via the Y direction address line 57. On the other hand, as shown in FIG. 7, the X direction address decoder circuit 58A selects a word decode line 72 ( . . . , 72m, 72m+1, . . . ) based on the address signal input via the X direction address line 55.

Further, the sense amplifier circuit 56B and the constant current circuit 58B operate when a read operation on the memory cell group 54 is carried out. In this case, as shown in FIG. 7, the sense amplifier circuit 56B is connected to the memory cell group 54 via read bit lines 13a and 13b, and detects read currents flowing through the respective read bit lines 13a and 13b when the read operation is carried out, to thereby read out information stored in the memory cells 1. Similarly, as shown in FIG. 7, the constant current circuit 58B is connected to the memory cell group 54 via a read switch 83 and a read word line 12, and controls the total current value of the read currents flowing through the read bit lines 13a and 13b (read currents flowing through the memory cells 1) during the read operation so that the total current value becomes constant. In this case, the read bit lines 13a and 13b correspond to “read lines” in the present invention.

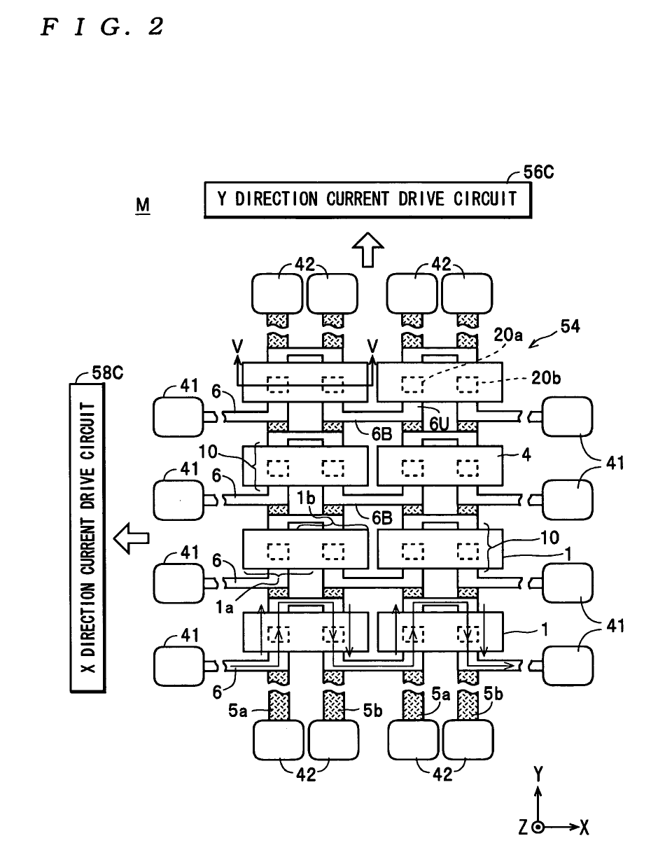

Further, the Y direction current drive circuit 56C and the X direction current drive circuit 58C operate when a write operation on the memory cell group 54 is carried out. More specifically, as shown in FIG. 2, the Y direction current drive circuit 56C is connected to the memory cell group 54 via write bit line leading electrodes 42 and write bit lines 5a and 5b (each of which is hereinafter also simply referred to as “the write bit line 5” when it is not required to make a distinction between the two write bit lines), and supplies write currents to the memory cell group 54 via the write bit lines 5a and 5b during the write operation. Similarly, the X direction current drive circuit 58C is connected to the memory cell group 54 via write word line leading electrodes 41 and write word lines (“first write lines” in the present invention) 6, and supplies write currents to the memory cell group 54 via the write word lines 6 when the write operation is carried out. In this case, the Y direction current drive circuit 56C supplies the write currents to the respective write bit lines (“second write lines” in the present invention) 5a and 5b such that the direction of a write current supplied to one of the write bit lines 5a and 5b is opposite to the direction of a write current supplied to the other one. Further, the write bit line 5a and the write word lines 6, and the write bit line 5b and the write word line 6 correspond to “conductors” in the present invention.

Next, a description will be given of a construction of the magnetic memory device M, which is concerned with an information write operation thereof.

FIG. 2 is a conceptual diagram showing the planar configuration of essential parts of the memory cell group 54, associated with the write operation. As shown in FIG. 2, the magnetic memory device M includes a plurality of write bit lines 5a and 5b and a plurality of write word lines 6 each intersecting with the plurality of write bit lines 5a and 5b. In this case, the write bit lines 5a and 5b and the write word lines 6 are configured such that parallel portions 10 extending in parallel to each other are formed in areas where the write bit lines 5a and 5b and the write word lines 6 intersect with each other. As shown in FIG. 2, the parallel portions 10 are formed by arranging the write word lines 6 extending in a rectangular waveform in the X direction (in other words, in a zigzag form in which a portion extending in the +Y direction and a portion extending in the −Y direction are alternately repeated with a portion that extends in the X direction being interposed therebetween), and the write bit lines 5a and 5b linearly extending along the Y direction, while the write bit lines 5a and 5b and a rising portion (portion extending in the +Y direction) and a falling portion (portion extending in the −Y direction) in the rectangular waveform of each write word line 6 are closely disposed in parallel to each other.

Further, the write bit line leading electrodes 42 are formed at opposite ends of each of the write bit lines 5a and 5b. The write bit line leading electrodes 42 are connected such that one of the electrodes 42 at the opposite ends of each of the write bit lines 5a and 5b (e.g., the write bit line leading electrode 42 on the upper side as viewed in FIG. 2) is connected to the Y direction current drive circuit 56C, and the other write bit line leading electrode 42 (e.g., the write bit line leading electrode 42 on the lower side as viewed in FIG. 2) is finally grounded. Similarly, the write word line leading electrodes 41 are formed at opposite ends of each write word line 6. The write word line leading electrodes 41 are connected such that one of the electrodes at the opposite ends of each write word line 6 (e.g., the write word line leading electrode 41 on the left side as viewed in FIG. 2) is connected to the X direction current drive circuit 58C, and the other electrode (e.g., the write word line leading electrode 41 on the right side as viewed in FIG. 2) is finally grounded.

As shown in FIGS. 2 and 3, each memory cell 1 includes annular magnetic layers 4a and 4b (which are also collectively referred to as “the annular magnetic layer 4”), and a pair of magnetoresistive effect-revealing bodies 20a and 20b. Further, each memory cell 1 is disposed at an intersection area where the write bit lines 5a and 5b and the write word lines 6 cross each other, such that the memory cell 1 includes the parallel portion 10 corresponding to the rising portion of the write word line 6, and the parallel portion 10 corresponding to the falling portion of the write word line 6 adjacent to the former parallel portion 10. Further, as shown in FIGS. 2 and 3, the memory cell 1 is configured such that the parallel portion 10 corresponding to the rising portion of the write word line 6 is formed as a storage element 1a, and the parallel portion 10 corresponding to the falling portion of the write word line 6 is formed as a storage element 1b.

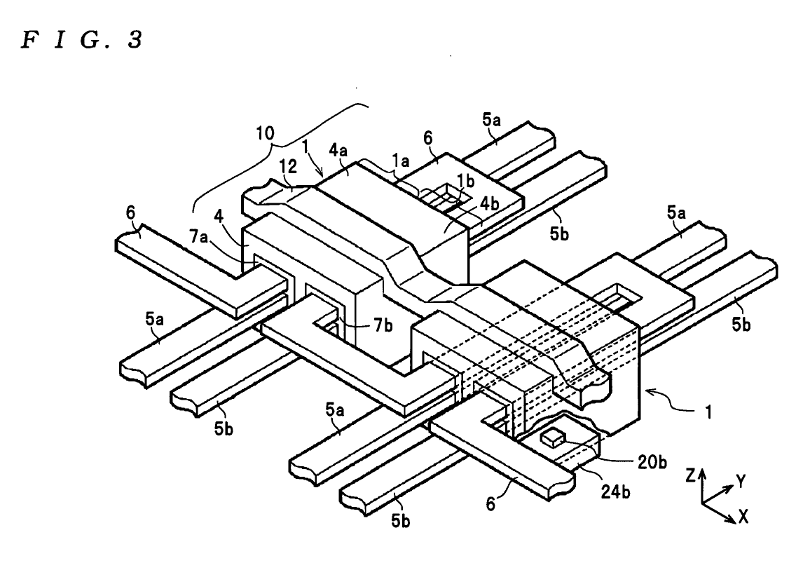

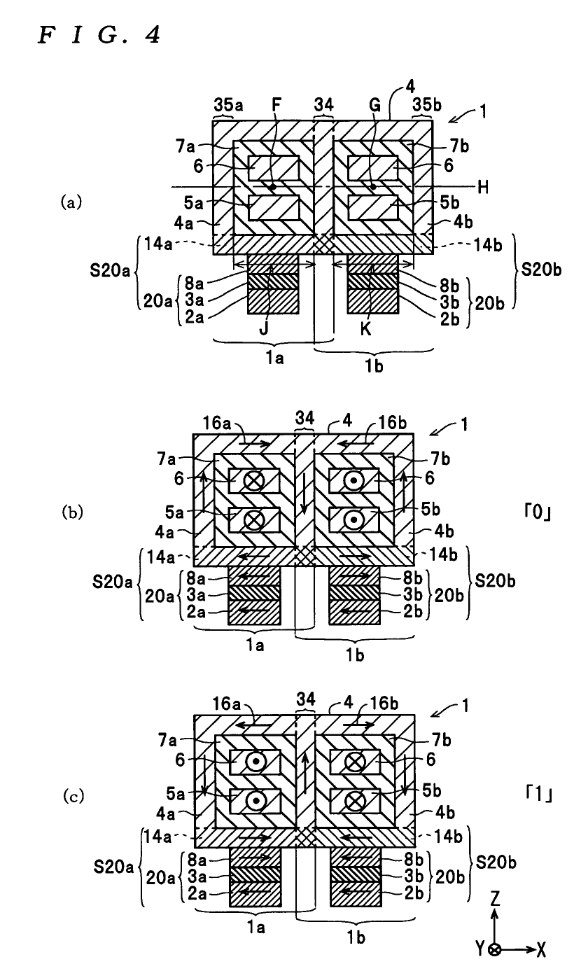

In this case, as shown in FIG. 4(a), the annular magnetic layer 4a is configured in an annular shape (e.g., a hollow quadrangular prismatic shape) with the direction along the laminating surfaces of the magnetoresistive effect revealing body 20a (the direction perpendicular to the direction of lamination of the magnetoresistive effect revealing body 20a; the Y direction in FIG. 4(a)) set as the direction of an axis thereof (the axis is indicated by the symbol F in FIG. 4(a)), and the write bit line 5a and the write word line 6 extend therethrough. In this case, in the annular magnetic layer 4a, the whole lower wall, as viewed in FIG. 4(a), forms a first magneto-sensitive layer 14a. Further, the write bit line 5a and the write word line 6 are arranged side by side in the Z direction, for example. Further, insulating films 7a are arranged between the write bit line 5a and the write word line 6, between the write bit line 5a and the annular magnetic layer 4a, and between the write word line 6 and the annular magnetic layer 4a, respectively, to thereby electrically insulate the write bit line 5a and the write word line 6 from each other, and electrically insulate the write bit line 5a and the write word line 6 from the annular magnetic layer 4a. Similarly, the annular magnetic layer 4b as well is configured in an annular shape (e.g., a hollow quadrangular prismatic shape) with the direction along the laminating surfaces of the magnetoresistive effect revealing body 20b (the direction perpendicular to the direction of lamination of the magnetoresistive effect revealing body 20b; the Y direction in FIG. 4(a)) set as the direction of an axis thereof (the axis is indicated by the symbol G in FIG. 4(a)), and the write bit line 5b and the write word line 6 extend therethrough. In this case, in the annular magnetic layer 4b, the whole lower wall, as viewed in FIG. 4(a), forms a first magneto-sensitive layer 14b. Further, the write bit line 5b and the write word line 6 are arranged side by side in the Z direction. Further, insulating films 7b are arranged between the write bit line 5b and the write word line 6, between the write bit line 5b and the annular magnetic layer 4b, and between the write word line 6 and the annular magnetic layer 4b, respectively, to thereby electrically insulate the write bit line 5b and the write word line 6 from each other, and electrically insulate the write bit line 5b and the write word line 6 from the annular magnetic layer 4b. Furthermore, the annular magnetic layers 4a and 4b are configured so as to be arranged side by side with the directions of the axes F and G thereof coincident with each other, and so as to share a portion (hereinafter, the portion is also referred to as “the shared portion 34”) sandwiched between the write bit line 5a and the write word line 6, and the write bit line 5b and the write word line 6, which extend through the associated annular magnetic layers 4a and 4b respectively,. More specifically, the annular magnetic layers 4a and 4b are arranged in parallel to each other in a state in which the directions of the axes F and G thereof are made coincident with each other, and at the same time they share one side wall (as the right side wall of the annular magnetic layer 4a, and the left side wall of the annular magnetic layer 4b, as viewed in FIG. 4(a); a predetermined portion in the present invention). Therefore, the shared portion 34 also serves as the right side wall of the annular magnetic layer 4a, and the left side wall of the annular magnetic layer 4b. Further, as shown in FIG. 4(a), the first magneto-sensitive layers 14a and 14b are arranged (more specifically, arranged side by side) on the same side (the lower side, as viewed in FIG. 4(a)) with respect to a plane H including the axes F and G. Further, the first magneto-sensitive layer 14a has the right side wall thereof, as viewed in FIG. 4(a), included in the shared portion 34, whereas the first magneto-sensitive layer 14b has the left side wall thereof, as viewed in FIG. 4(a), included in the shared portion 34. As a result, the first magneto-sensitive layers 14a and 14b are arranged side by side in a state where they are sharing one end thereof (as the right end of the first magneto-sensitive layer 14a and the left end of the first magneto-sensitive layer 14b), and further are located on the same plane.

On the other hand, as shown in FIG. 4(a), the magnetoresistive effect revealing body 20a is comprised of a first magnetic layer 2a, a tunnel barrier layer (“non-magnetic layer” in the present invention) 3a, and a second magnetic layer 8a (“second magneto-sensitive layer” in the present invention; hereinafter also referred to as “the second magneto-sensitive layer 8a”), which are deposited on a conductive layer 24a, described later, in the mentioned order. Further, the magnetoresistive effect revealing body 20a is arranged such that the second magneto-sensitive layer 8a is disposed on a surface of the central portion or the vicinity of the first magneto-sensitive layer 14a (within an area sandwiched by the left side wall 35a of the annular magnetic layer 4a and the shared portion 34, indicated by the symbol J in FIG. 4(a)) in a state where the second magneto-sensitive layer 8a is electrically connected to the first magneto-sensitive layer 14a. In the present embodiment, the magnetoresistive effect revealing body 20a is disposed on the central portion of the first magneto-sensitive layer 14a, by way of example. With this configuration, the magnetoresistive effect revealing body 20a forms a TMR film S20a (“laminate” in the present invention) together with the first magneto-sensitive layer 14a. In the TMR film S20a, electric current flows in a direction perpendicular to the laminating surfaces of the magnetoresistive effect revealing body 20a.

Similarly, as shown in FIG. 4(a), the magnetoresistive effect revealing body 20b is comprised of a first magnetic layer 2b, a tunnel barrier layer (“non-magnetic layer” in the present invention) 3b, and a second magnetic layer 8b (“second magneto-sensitive layer” in the present invention; hereinafter also referred to as “the second magneto-sensitive layer 8b”), which are deposited on the conductive layer 24a, described later, in the mentioned order. Further, the magnetoresistive effect revealing body 20b is arranged such that the second magneto-sensitive layer 8b is disposed on a surface of the central portion or the vicinity of the first magneto-sensitive layer 14b (within an area sandwiched by the right side wall 35b of the annular magnetic layer 4b and the shared portion 34, indicated by the symbol K in FIG. 4(a)) in a state where the second magneto-sensitive layer 8b is electrically connected to the first magneto-sensitive layer 14b. In the present embodiment, the magnetoresistive effect revealing body 20b is disposed on the central portion of the first magneto-sensitive layer 14b, by way of example. With this configuration, the magnetoresistive effect revealing body 20b forms a TMR film S20b (“laminate” in the present invention) together with the first magneto-sensitive layer 14b. In the TMR film S20b, electric current flows in a direction perpendicular to the laminating surfaces of the magnetoresistive effect revealing body 20b.

In this case, the first magneto-sensitive layer 14a and the second magneto-sensitive layer 8a are magnetically exchange-coupled with each other. Similarly, the first magneto-sensitive layer 14b and the second magneto-sensitive layer 8b as well are magnetically exchange-coupled with each other. On the other hand, the first magnetic layers 2a and 2b have magnetization directions fixed in advance in the same direction. It should be noted that in FIG. 4, for purposes of description of the film structures of the TMR films S20a and S20b, the sizes of the TMR films S20a and S20b are exaggerated to be relatively larger than those of other neighboring component parts, and the thicknesses of the first magneto-sensitive layers 14a and 14b are exaggerated to be relatively larger than those of the other neighboring component parts.

The TMR film S20a is configured such that when voltage in a direction perpendicular to the laminating surfaces thereof is applied across the first magnetic layer 2a and the second magneto-sensitive layer 8a, electrons of one of the first magnetic layer 2a and the second magneto-sensitive layer 8a penetrate the tunnel barrier layer 3a to move to the other one of the first magnetic layer 2a and the second magneto-sensitive layer 8a, thereby causing a tunnel current to flow. That is, the TMR film S20a is configured to be capable of attaining enhancement of the storing speed and the access speed thereof. The tunnel current varies with a relative angle between the spin of the first magnetic layer 2a at an interface between the first magnetic layer 2a and the tunnel barrier layer 3a and the spin of the second magneto-sensitive layer 8a at an interface between the second magneto-sensitive layer 8a and the tunnel barrier layer 3a. More specifically, the resistance value becomes minimum when the spin of the first magnetic layer 2a and the spin of the second magneto-sensitive layer 8a are parallel to each other, whereas the resistance value becomes maximum when the spin of the first magnetic layer 2a and the spin of the second magneto-sensitive layer 8a are antiparallel to each other. The same applies to the TMR film S20b. The rate of change in magnetoresistance (MR ratio) is defined using the above resistance values by the following equation:
MR ratio=dR/R

wherein “dR” represents the difference between the resistance value assumed when the spins are parallel to each other and the resistance value assumed when the spins are antiparallel to each other, and “R” represents the resistance value assumed when the spins are parallel to each other.

Further, the resistance value to the tunnel current (hereinafter also referred to as “the tunnel resistance Rt”) is largely dependent on the film thickness T of the tunnel barrier layers 3a and 3b. More specifically, the tunnel resistance Rt exponentially increases according to the film thickness T of the tunnel barrier layers 3a and 3b in a low-voltage region, as expressed by the following equation:
Rt∝ exp(2χ^{T}), χ={8π²m*(φ·Ef)^{0.5}}/h

wherein “φ” represents the height of barrier, “m*” an effective mass of an electron, “Ef” Fermi energy, and “h” Planck's constant. In general, in a memory element employing storage elements, it is considered appropriate that the tunnel resistance Rt is approximately several 10 kΩ·(μm)², so as to perform matching of the storage elements with semiconductor devices, such as transistors. However, to attain a higher density and operational speed of the magnetic memory device, it is preferable that the tunnel resistance Rt is not higher than 10 kΩ·(μm)², and more preferably not higher than 1 kΩ·(μm)². Therefore, to attain the above tunnel resistance Rt, it is preferable that the thickness T of the tunnel barrier layers 3a and 3b is not more than 2 nm, more preferably not more than 1.5 nm.

It should be noted that although the above tunnel resistance Rt can be reduced by reducing the thickness T of the tunnel barrier layers 3a and 3b, a leakage current occurs due to asperities on joining interfaces between the tunnel barrier layers 3a and 3b and the first magnetic layers 2a and 2b and between the tunnel barrier layers 3a and 3b and the second magneto-sensitive layers 8a and 8b, which sometimes lowers the MR ratio. To prevent lowering of the MR ratio, it is necessary to set the thickness T of each of the tunnel barrier layers 3a and 3b to a thickness large enough to inhibit the leakage current from flowing. More specifically, it is preferable that the thickness is set at a value not less than 0.3 nm.

Further, the TMR films S20a and S20b are configured to have a coercive force difference type structure, and therefore it is preferable that the first magnetic layers 2a and 2b are configured to have a coercive force larger than that of the second magneto-sensitive layers 8a and 8b. More specifically, it is preferable that the coercive force of the first magnetic layers 2a and 2b is larger than (50/4π)×10³ A/m, particularly preferably not smaller than (100/4π)×10³ A/m. This configuration makes it possible to prevent the magnetization directions of the first magnetic layers 2a and 2b from being adversely affected by an undesired magnetic field, such as an external disturbance magnetic field. The first magnetic layers 2a and 2b are composed e.g., of a cobalt-iron alloy (CoFe) having a thickness of 5 nm. Further, the first magnetic layers 2a and 2b can also be made e.g., of a single cobalt (Co), a cobalt-platinum alloy (CoPt), a nickel-iron-cobalt alloy (NiFeCo), or the like. The second magneto-sensitive layers 8a and 8b can be formed of a single cobalt (Co), a cobalt-iron alloy (CoFe), a cobalt-platinum alloy (CoPt), a nickel-iron alloy (NiFe), or a nickel-iron-cobalt alloy (NiFeCo). Further, it is desirable that the axis of easy magnetization of each of the first magnetic layers 2a and 2b and that of each of the second magneto-sensitive layers 8a and 8b are parallel to each other so as to stabilize the magnetization directions of the first magnetic layers 2a and 2b and those of the second magneto-sensitive layers 8a and 8b in a state where they are parallel or antiparallel to each other.

With the above-described configuration, in the annular magnetic layer 4, there is generated a circulating magnetic field by the write current flowing through the parallel portion 10 of the write bit lines 5 and the write word lines 6. The circulating magnetic field is inverted depending on the directions of electric currents flowing through the write bit lines 5 and the write word lines 6. It is preferable that the annular magnetic layer 4 is composed e.g., of a nickel-iron alloy (NiFe), and configured such that the coercive force of the first magneto-sensitive layers 14a and 14b is smaller than that of the first magnetic layers 2a and 2b when the coercive force of the first magneto-sensitive layers 14a and 14b is not larger than (100/4π)×10³ A/m. This is because when the coercive force of the first magneto-sensitive layers 14a and 14b is larger than (100/4π)×10³ A/m, the TMR films S20a and S20b themselves can be deteriorated by heat generated by increased write currents when the direction of the circulating magnetic field is inverted. Furthermore, when the coercive force of the first magneto-sensitive layers 14a and 14b becomes not smaller than that of the first magnetic layers 2a and 2b, the write currents are increased to change the magnetization directions of the first magnetic layers 2a and 2b as magnetization fixed layers, which can destroy the storage elements 1a and 1b. Further, it is preferable that the magnetic permeability of the annular magnetic layer 4 is higher so as to cause the circulating magnetic field by the write bit lines 5 and the write word lines 6 to be concentrated on the annular magnetic layer 4. More specifically, it is preferable that the magnetic permeability of the annular magnetic layer 4 is not lower than 2000, more preferably not lower than 6000.

Furthermore, it is preferable that the film thickness of the first magneto-sensitive layers 14a and 14b is set to a value within a range of not less than 0.5 nm to not more than 40 nm, more preferably within a range of not less than 0.5 nm to not more than 30 nm. If the film thickness of the first magneto-sensitive layers 14a and 14b is defined (set) within the above range, when the magnetization directions of the first magneto-sensitive layers 14a and 14b and those of the second magneto-sensitive layers 8a and 8b are inverted, it is possible to balance the total value of write currents caused to flow through the write word line 6 and the write bit line 5a extending through the annular magnetic layer 4a (total value of write currents caused to flow through the storage element 1a), and the total value of write currents caused to flow through the write word line 6 and the write bit line 5b extending through the annular magnetic layer 4b (total value of write currents caused to flow through the storage element 1b). This can result in the decreased amount of the write currents flowing through the whole memory cell 1.

In this case, when the thickness of the first magneto-sensitive layers 14a and 14b is not less than 50 nm, the current difference between the total value of the write currents on the storage element 1a side and the total value of the write currents on the storage element 1b side increases, thereby causing an imbalance in the total values. Therefore, also to a storage element (one of the elements 1a and 1b) with a smaller total value of write currents flowing therethrough, it is required to forcibly supply write currents having the same magnitudes as those of write currents caused to flow though a storage element (the other one of the elements 1a and 1b) with a larger total value of write currents. Moreover, the respective total values of the write currents supplied to the storage elements 1a and 1b increase as a whole. As a result, when the thickness of the first magneto-sensitive layers 14a and 14b is not less than 50 nm, the total amount of write currents caused to flow though the memory cell 1 becomes larger. On the other hand, when the thickness of the first magneto-sensitive layers 14a and 14b is less than 50 nm, the current difference between the total value of write currents on the storage element 1a side and the total value of write currents on the storage element 1b side tends to be slightly reduced to improve the balance therebetween, and as the thickness (film thickness) of the first magneto-sensitive layers 14a and 14b becomes smaller, the total value of write currents on the storage element 1a side and that of write currents on the storage element 1b side both tend to be lower. Particularly when the above thickness is not more than 40 nm, the current difference between the total values of write currents on the storage element 1a side and the storage element 1b side tends to be further reduced to further improve the balance therebetween. Furthermore, when the thickness is not more than 30 nm, the current difference between the total values of write currents on the storage element 1a side and the storage element 1b side tends to be still reduced to further improve the balance therebetween. However, to manufacture the first magneto-sensitive layers 14a and 14b as stable films, it is preferable to set the thickness of the first magneto-sensitive layers 14a and 14b to a value not less than 0.5 nm.

The write bit lines 5 and the write word lines 6 are each formed e.g., by depositing titanium (Ti) having a thickness of 10 nm, titanium-nitride (TiN) having a thickness of 10 nm, and aluminum (Al) having a thickness of 500 nm in the mentioned order.

Next, a configuration of the magnetic memory device, which is concerned with an information read operation, will be described with reference to FIGS. 3, 5, and 6.

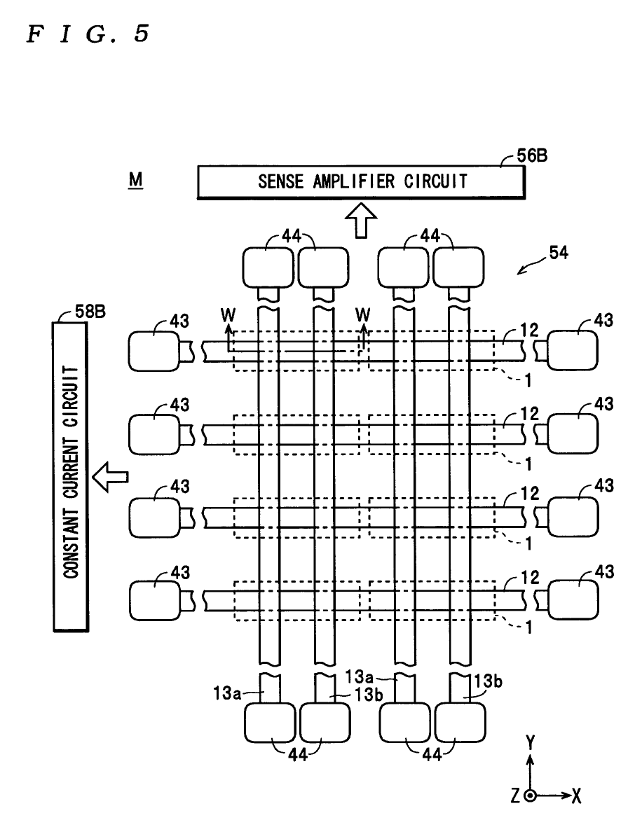

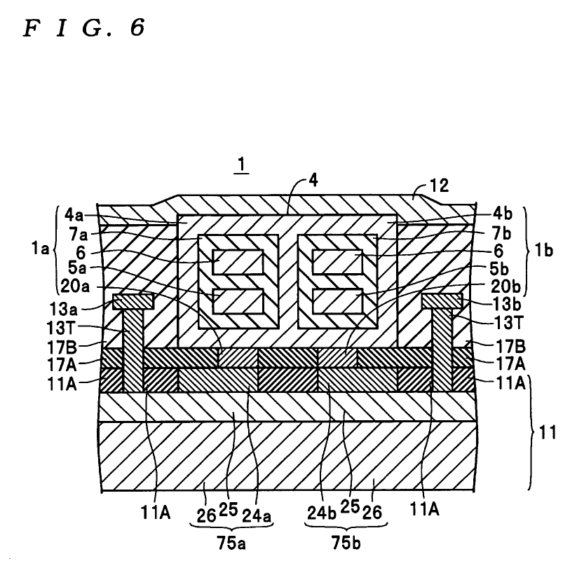

Referring to FIG. 5, each memory cell 1 is disposed at each of intersections where a plurality of read word lines 12 and a plurality of read bit lines 13a and 13b intersect with each other. In this case, as shown in FIG. 6, the storage elements 1a and 1b of the memory cell 1 are each comprised of a pair of magnetoresistive effect revealing bodies 20a and 20b, and an annular magnetic layer 4 (4a and 4b), which are deposited in the mentioned order on a substrate in which a pair of Schottky diodes 75a and 75b (hereinafter also simply referred to as “the diodes 75a and 75b”) are formed. Further, the underside surfaces (side in which the magnetoresistive effect revealing bodies 20a and 20b are formed) of the memory cells 1 (1a and 1b) are connected to the read bit lines 13a and 13b via the diodes 75a and 75b, and connection layers 13T and 13T, respectively. On the other hand, as shown in FIGS. 3 and 6, the storage elements 1a and 1b each have a top surface thereof (on a side thereof opposite from the magnetoresistive effect revealing bodies 20a and 20b) connected to the read word line 12. In this case, the read bit lines 13a and 13b are for supplying read currents to the pair of storage elements 1a and 1b of the memory cell 1, respectively, and as shown in FIG. 5, each have opposite ends thereof provided with read bit line leading electrodes 44, respectively. On the other hand, the read word lines 12 are for guiding the read currents having flowed through the storage elements 1a and 1b to the ground (earth potential), and each have opposite ends thereof provided with read word line leading electrodes 43, respectively.

Referring to FIG. 6, the diode 75a is comprised of a base plate 26, an epitaxial layer 25 deposited on the base plate 26, and a conductive layer 24a deposited on the epitaxial layer 25, and has a Schottky barrier formed between the conductive layer 24a and the epitaxial layer 25. Similarly, as shown in FIG. 6, the diode 75b as well is comprised of a base plate 26, an epitaxial layer 25 deposited on the base plate 26, and a conductive layer 24b deposited on the epitaxial layer 25, and has a Schottky barrier formed between the conductive layer 24b and the epitaxial layer 25. Further, the diode 75a and the diode 75b are electrically connected to each other via the magnetoresistive effect revealing bodies 20a and 20b and the annular magnetic layer 4, while being electrically insulated from each other at the other portions. It should be noted that in FIG. 6, portions designated by reference numerals 11A, 17A, and 17B are formed by insulating layers.

Next, a circuit configuration of the magnetic memory device M, which is concerned with a read operation, will be described with reference to FIG. 7.

Referring to FIG. 7, in the magnetic memory device M, the memory cell 1 arranged on each bit string of the memory cell group 54, and part of a read circuit including the sense amplifier circuit 56B form a unit read circuit 80 ( . . . , 80n, 80n+1, . . . ), which is a repetition unit of the read circuit, and a plurality of the unit read circuits 80 are arranged in parallel in the direction of the bit string. Each unit read circuit 80 is connected to the Y direction address decoder circuit 56A via a bit decode line 71 ( . . . , 71n, 71n+1, . . . ), and connected to the output buffer 52B via the Y direction read data bus 62.

Further, the respective storage elements 1a and 1b of each memory cell 1 included in each unit read circuit 80 have one ends thereof connected to the read bit lines 13a and 13b of each unit read circuit 80 via the pair of diodes 75a and 75b, respectively. On the other hand, the other ends of the respective storage elements 1a and 1b of each memory cell 1 included in each unit read circuit 80 are connected to the read word lines 12 ( . . . , 12m, 12m+1, . . . ), respectively.

In this case, one ends of the respective read word lines 12 are connected to read switches 83 ( . . . , 83m, 83m+1, . . . ) via the read word line leading electrodes 43 (see FIG. 5), and further the respective read switches 83 are connected to the shared constant current circuit 58B. Further, the respective read switches 83 are connected to the X direction address decoder circuit 58A via the word decode lines 72 ( . . . , 72m, 72m+1, . . . ), and each configured to be switched into conduction when a selection signal is inputted thereto from the X direction address decoder circuit 58A.

The respective read bit lines 13a and 13b have one ends thereof connected to the sense amplifier circuit 56B via the read bit line leading electrodes 44 (see FIG. 5), and the other ends thereof finally connected to the ground. The sense amplifier circuit 56B has the function of detecting information (binary information) stored in the memory cell 1, through which read currents have flowed, of each unit read circuit 80 based on the difference between the respective read currents that flow through the pair of read bit lines 13a and 13b of the unit read circuit 80, and outputting the detected information to the Y direction read data bus 62 via an output line 82 ( . . . , 82n, 82n+1, . . . ).

Next, a description will be given of the operations of the magnetic memory device M.

First, the write operation of the memory cell 1 will be described with reference to FIGS. 2, and 4(b) and 4(c).

As shown in FIG. 4(b), a write current is caused to flow through the write word line 6 such that the current flows through a portion of the write word line 6 in the storage element 1a from the front side to the rear of the sheet, as viewed in FIG. 4(b) (in the +Y direction). Further, in the parallel portions 10 (see FIG. 2) of the storage elements 1a and 1b, write currents are caused to flow through the write bit lines 5a and 5b such that the current flow through the write bit lines 5a and 5b in the same directions as the direction of the current flowing through the write word line 6. More specifically, as shown in FIG. 4(b), a write current is caused to flow through the write bit line 5a from the front side to the rear side of the sheet, as viewed in FIG. 4(b) (in the +Y direction), and a write current is caused to flow through the write bit line 5b from the rear side to the front side of the sheet, as viewed in FIG. 4(b) (in the −Y direction). In this case, in the storage element 1a, a circulating magnetic field 16a circulating in the clockwise direction is generated within the annular magnetic layer 4a, whereas in the storage element 1b, a circulating magnetic field 16b circulating in the counterclockwise direction is generated within the annular magnetic layer 4b. As a result, in the storage element 1a, the magnetization directions of the first magneto-sensitive layer 14a and the second magneto-sensitive layer 8a become the −X direction, whereas in the storage element 1b, the magnetization directions of the first magneto-sensitive layer 14b and the second magneto-sensitive layer 8b become the +X direction. This means that the magneto-sensitive layers (the first magneto-sensitive layer 14a and the second magneto-sensitive layer 8a) of the storage element 1a, and the magneto-sensitive layers (the first magneto-sensitive layer 14b and the second magneto-sensitive layer 8b) of the storage element 1b are magnetized in directions antiparallel to each other. Further, in the shared portion 34 of the annular magnetic layers 4a and 4b, the directions of the circulating magnetic fields 16a and 16b coincide with each other. Therefore, as shown in FIG. 4(b), in the storage element 1a, the magnetization direction of the second magneto-sensitive layer 8a and that of the first magnetic layer 2a coincide with (parallel to) each other. On the other hand, in the storage element 1b, the magnetization direction of the second magneto-sensitive layer 8b and that of the first magnetic layer 2b are reverse (antiparallel) to each other. As a result, information (e.g., “0”) is stored in the memory cell 1.

On the other hand, as shown in FIG. 4(c), when electric currents are caused to flow through the write word lines 6 and the write bit lines 5a and 5b in directions reverse to those of flow of the currents in FIG. 4(b), in the storage element 1a, a circulating magnetic field 16a circulating in the counterclockwise direction is generated within the annular magnetic layer 4a, whereas in the storage element 1b, a circulating magnetic field 16b circulating in the clockwise direction is generated within the annular magnetic layer 4b. As a result, in the storage element 1a, the magnetization directions of the first magneto-sensitive layer 14a and the second magneto-sensitive layers 8a become the +X direction, whereas in the storage element 1b, the magnetization directions of the first magneto-sensitive layer 14b and the second magneto-sensitive layer 8b become the −X direction. This means that the magneto-sensitive layers of the storage element 1a, and the magneto-sensitive layers of the storage element 1b are magnetized in directions antiparallel to each other. It should be noted that in this case as well, in the shared portion 34 of the annular magnetic layers 4a and 4b, the directions of the circulating magnetic fields 16a and 16b coincide with each other (directions reverse to the directions of the circulating magnetic fields 16a and 16b in FIG. 4(b)). Therefore, as shown in FIG. 4(c), in the storage element 1a, the magnetization direction of the second magneto-sensitive layer 8a and that of the first magnetic layer 2a are reverse (antiparallel) to each other. In contrast, in the storage element 1b, the magnetization direction of the second magneto-sensitive layer 8b and that of the first magnetic layer 2b coincide with (parallel to) each other. As a result, information (e.g., “1”) is stored in the memory cell 1.

In this case, if the magnetization direction of the first magnetic layer 2a or 2b is parallel to that of the associated one of the second magneto-sensitive layer 8a and 8b, the storage element 1a or 1b is in a low-resistance state in which a large tunnel current flows therethrough, whereas if the associated magnetization directions are antiparallel to each other, the storage element 1a or 1b is in a high-resistance state in which only a small tunnel current flows therethrough. That is, one of the storage element la and the storage element 1b as a pair is necessarily in the low-resistance state, and at the same time the other is necessarily in the high-resistance state, whereby information is stored. It should be noted that when write currents are caused to flow through the write bit line 5 and the write word line 6 in directions opposite to each other, or when a write current is caused to flow through only one of them, the magnetization directions of the respective second magneto-sensitive layers 8a and 8b are not inverted, and therefore rewriting of data is not performed.

Next, the read operation of the magnetic memory device M will be described with reference to FIGS. 1, 7, and 8.

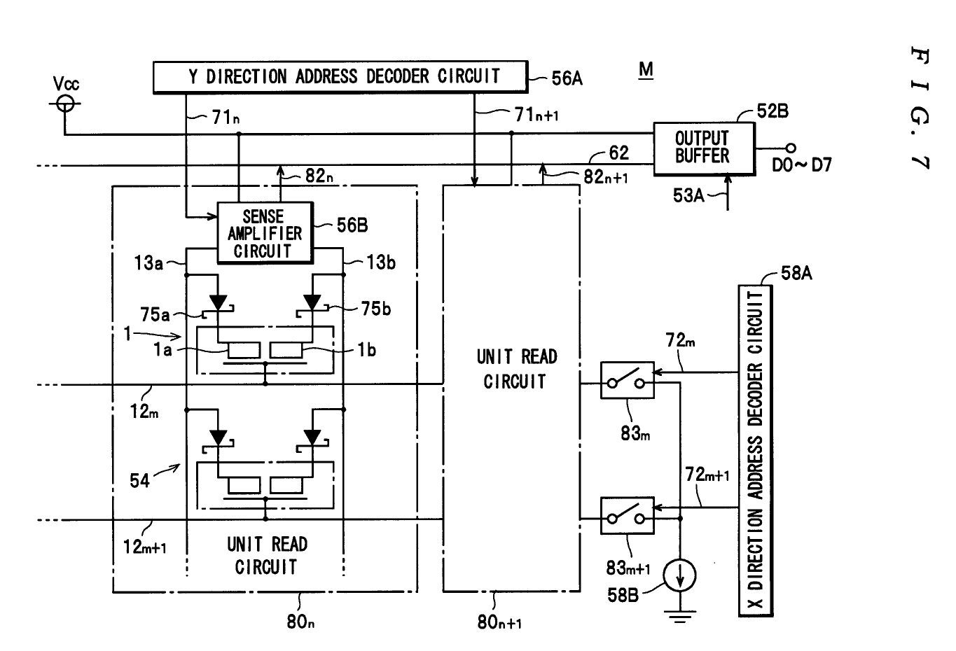

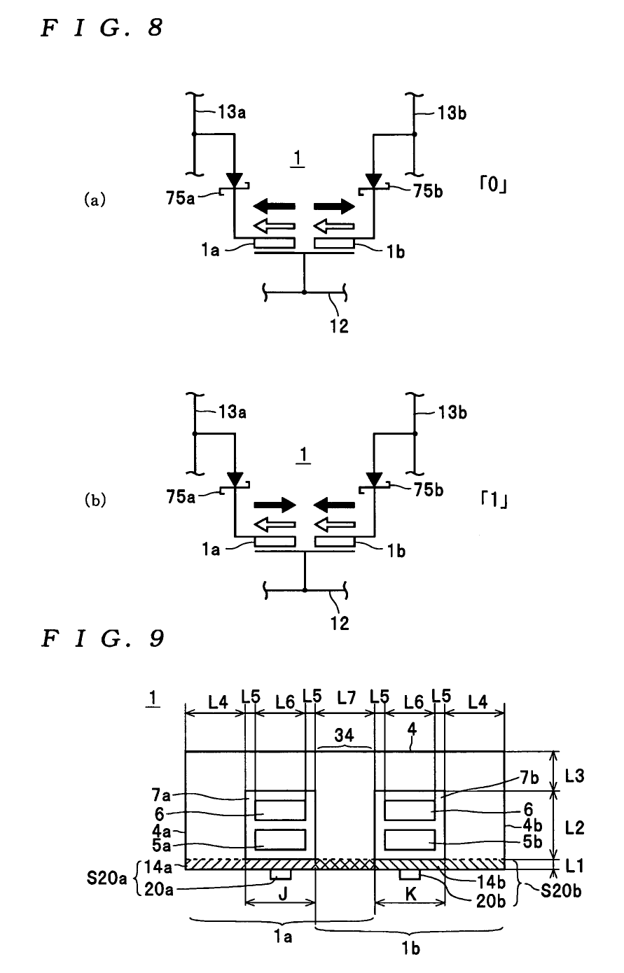

First, the Y direction address decoder circuit 56A having the address signal input thereto via the address buffer 51 selects one of the plurality of bit decode lines 71 based on the address signal, and delivers a control signal to the associated sense amplifier circuit 56B. Then, the sense amplifier circuit 56B having the control signal input thereto applies a voltage to the read bit lines 13a and 13b connected thereto. This gives positive potentials to the TMR films S20a and S20b of the respective storage elements 1a and 1b. On the other hand, the X direction address decoder circuit 58A having the address signal input thereto via the address buffer 51 selects one of the plurality of word decode lines 72 based on the address signal, to thereby drive associated read switches 83 to thereby cause the read switch 83 to switch into an ON state (conduction). This causes read currents to flow through a memory cell 1 disposed at an intersection where the selected bit decode line 71 (i.e., the read bit lines 13a and 13b) and the word decode line 72 (i.e., the read word line 12) intersect with each other. In this case, one of the storage elements 1a and 1b of the memory cell 1 is held in the low-resistance state, and the other is held in the high-resistance state, according to the value of information stored in the memory cell 1, and the sum total of read currents that flow through the memory cell 1 is held at a fixed value by the constant current circuit 58B. As a result, a larger amount of read current flows through one of the storage elements la and 1b, and at the same time a smaller amount of read current flows through the other. For example, in a state of the memory cell 1 illustrated in FIG. 8(a), in the storage element 1a, the magnetization direction of the first magnetic layer 2a and that of the second magneto-sensitive layer 8a are parallel to each other, and in the storage element 1b, the magnetization direction of the first magnetic layer 2b and that of the second magneto-sensitive layer 8b are antiparallel to each other, and therefore the storage element 1a is in the low-resistance state, and the storage element 1b is in the high-resistance state. In contrast, in a state of the memory cell 1 illustrated in FIG. 8(b), the magnetization direction of the first magnetic layer 2a of the storage element 1a and that of the second magneto-sensitive layer 8a of the storage element 1b are reverse to the magnetization directions thereof illustrated in FIG. 8(a), and therefore the storage element 1a is in the high-resistance state, and the storage element 1b is in the low-resistance state.

On the other hand, the sense amplifier circuit 56B detects the difference between the amounts of electric currents flowing through the respective storage elements 1a and 1b to thereby obtain information (binary information) stored in the memory cell 1. Further, the sense amplifier circuit 56B outputs the obtained information to the external data terminals D0 to D7 via the output buffer 52B. Thus, read of the binary information stored in the memory cell 1 is completed.

As described hereinabove, the magnetic memory device M includes the plurality of write bit lines 5a and 5b and the plurality of write word lines 6 extending so that the write word lines 6 intersect with the write bit lines 5a and 5b respectively, and at the same time comprises the storage elements 1a and 1b configured as above, including the TMR films S20a and S20b configured as above and the annular magnetic layer 4 surrounding the write bit lines 5a and 5b and the write word lines 6, whereby synthetic fields generated by causing electric currents to flow through the write bit line 5a and the write word line 6 and through the write bit line 5b and the write word line 6 can be made larger compared with a magnetic memory device configured to have the write bit lines 5a and 5b and the write word lines 6 intersecting with each other. Further, magnetic fluxes generated around the write bit lines 5a and 5b and the write word lines 6 by electric currents flowing through both the write bit lines 5a and 5b and the write word lines 6 can be confined within closed magnetic circuits formed by the annular magnetic layers 4a and 4b. This makes it possible to reduce occurrence of leakage fluxes, thereby making it possible to largely reduce adverse influence of leakage fluxes on adjacent memory cells. Further, the magnetic memory device M is configured such that in one memory cell 1, the pair of storage elements 1a and 1b share a portion (shared portion 34) of the annular magnetic layer 4 with each other, whereby compared with a magnetic memory device configured to have the annular magnetic layers 4a and 4b spaced from each other, it is possible to increase the magnetic flux density in the shared portion 34 of the annular magnetic layers 4a and 4b. As a result, it is possible to increase the strengths of the circulating magnetic fields 16a and 16b within the annular magnetic layers 4a and 4b. Combined with the reduced generation of leakage fluxes, this makes it possible to invert the magnetization directions of the second magneto-sensitive layers 8a and 8b with smaller write currents.

Furthermore, since the thickness of each of the first magneto-sensitive layers 14a and 14b of the respective storage elements 1a and 1b is set to be within the range of not less than 0.5 nm and not more than 40 nm, it is possible to ensure a thickness of 0.5 nm or more, which enables the first magneto-sensitive layers 14a and 14b to be stably manufactured as magnetic films. This makes it possible to largely enhance the yield of the magnetic memory device M. Further, since the thickness of the first magneto-sensitive layers 14a and 14b is set at not more than 40 nm, a demagnetizing field due to the thickness is decreased, thereby making it possible to reduce the current values of write currents flowing through the storage elements 1a and 1b, while ensuring the balance between the write currents to some degree. Moreover, since the thickness of the first magneto-sensitive layers 14a and 14b is set at to be not more than 30 nm, a demagnetizing field due to the thickness is further decreased, thereby making it possible to further reduce the current values of write currents flowing through the storage elements 1a and 1b, while further balancing the write currents.

Further, the magneto-sensitive layers (the first magneto-sensitive layer 14a and the second magneto-sensitive layer 8a and the first magneto-sensitive layer 14b and the second magneto-sensitive layer 8b) are configured so as to be magnetized in directions antiparallel to each other by magnetic fields generated around the write bit lines 5a and 5b and the write word lines 6. This makes it possible to always align the directions of the circulating magnetic fields 16a and 16b generated in the shared portion 34 of the annular magnetic layers 4a and 4b when electric currents are caused to flow through the write bit lines 5a and 5b and the write word lines 6 of the pair of storage elements 1a and 1b, so that it is possible to reliably increase the magnetic flux density in the shared portion 34 of the annular magnetic layers 4a and 4b. This makes it possible to increase the strengths of the circulating magnetic fields 16a and 16b within the annular magnetic layers 4a and 4b, thereby making it possible to invert the magnetization directions of the second magneto-sensitive layers with smaller write currents.

Furthermore, the magneto-sensitive layers are formed of the first magneto-sensitive layer 14a and the second magneto-sensitive layer 8a, and the first magneto-sensitive layer 14b and the second magneto-sensitive layer 8b, which are formed such that each pair of the first and second layers can be magnetically exchange-coupled with each other, and the first magneto-sensitive layers 14a and 14b are formed of part of the annular magnetic layers 4a and 4b. This makes it possible to select a material having a high polarizability as a material for forming the second magneto-sensitive layers 8a and 8b which form the magneto-sensitive layers, and hence it is possible to increase the rate of change in the magnetoresistance of the storage elements 1a and 1b.

It should be noted that the present invention is by no means limited to the above-described embodiment. For example, although in the above-described magnetic memory device M, the description has been given, by way of example, of the memory cell 1 configured to include the first magneto-sensitive layers 14a and 14b and the second magneto-sensitive layers 8a and 8b of the annular magnetic layer 4, it is also possible to construct a memory cell in which the second magneto-sensitive layers 8a and 8b are omitted to include only the first magneto-sensitive layers 14a and 14b of the annular magnetic layer 4 as magneto-sensitive layers. Further, it is also possible to construct a memory cell in which a non-magnetic conductive layer is provided between the first magneto-sensitive layers 14a and 14b and the second magneto-sensitive layers 8a and 8b of the annular magnetic layer 4, whereby the first magneto-sensitive layers 14a and 14b and the second magneto-sensitive layers 8a and 8b are antiferromagnetically coupled with each other. Further, although in the above-described embodiment, the description has been given of the example in which the present invention is applied to the memory cell having the TMR films S20a and S20b configured to have a coercive force difference type structure, it is possible to apply the present invention to a memory cell in which the TMR films are each formed as a switching bias type.

Further, although in the above-described magnetic memory device M, the description has been given, by way of example, of the memory cell 1 which is configured so as to include the pair of annular magnetic layers 4a and 4b, and store one-bit information by the construction where the pair of the annular magnetic layers 4a and 4b share a portion thereof with each other, the present invention can be applied to a memory cell which includes a storage element (e.g., the storage element 1a illustrated in FIG. 4) having one magnetoresistive effect revealing body 20a shown in FIG. 4 and one annular magnetic layer 4a shown in FIG. 4, and stores one-bit information using the one annular magnetic layer 4a and the one magnetoresistive effect revealing body 20a. In this case, the thickness of the first magneto-sensitive layers 14a and 14b is set in a range of not less than 0.5 nm to not more than 40 nm, preferably in a range of not less than 0.5 nm to not more than 30 nm. Further, in this case, the memory cell can be configured such that both the write word line 6 and the write bit line 5a are arranged in the annular magnetic layer 4a, or that only the write bit line 5a is arranged inside the annular magnetic layer 4a with the write word line 6 disposed outside the annular magnetic layer 4a.

Further, the present invention can also be applied to a memory cell which is configured such that at least one storage element having the same configuration as that of the storage element 1a (or storage element 1b) is arranged side by side in a line with the axes of the storage elements being aligned with each other on the left side wall 35a of the annular magnetic layer 4a of the storage element 1a or the right side wall 35b of the annular magnetic layer 4b of the storage element 1b in the above-described memory cell 1, whereby one-bit information is stored by the three or more storage elements. In this case, the thickness of the first magneto-sensitive layers 14a and 14b is set in a range of not less than 0.5 nm to not more than 40 nm (preferably in a range of not less than 0.5 nm to not more than 30 nm).

### EXAMPLES

Next, the invention will be described in detail by giving examples.

(Experiment 1)

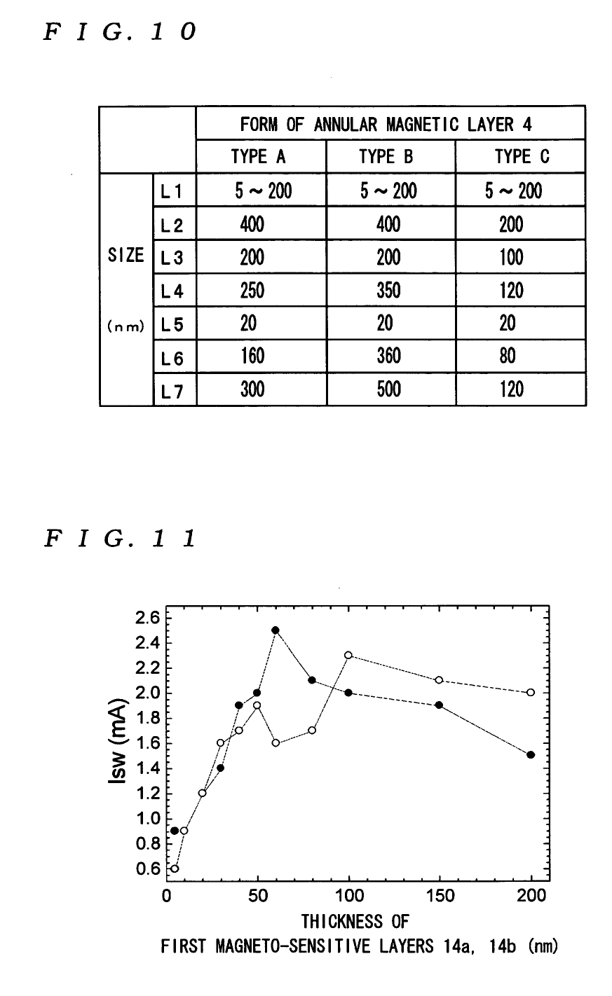

An annular magnetic layer 4 of Type A was assumed in which the sizes L2 to L7 of portions shown in FIG. 9 were set at lengths indicated in the column of Type A shown in FIG. 10, and write currents (Isw) which flowed though storage elements 1a and 1b of the annular magnetic layer 4 of Type A were determined by simulation, when the thickness L1 of a first magneto-sensitive layer 14a (portion hatched by rising rightward oblique lines in FIG. 9) and a first magneto-sensitive layer 14b (portion hatched by descending rightward oblique lines in the figure) of the annular magnetic layer 4 of Type A was changed from 5 nm, to 10 nm, 20 nm, 30 nm, 40 nm, 50 nm, 60 nm, 80 nm, 100 nm, 150 nm, and 200 nm. Here, the term “write current” is intended to mean an electric current required for inverting the magnetization directions of the first magneto-sensitive layers 14a and 14b, and second magneto-sensitive layers 8a and 8b (the same applies to the following experiment). Further, a characteristic diagram (FIG. 11) was prepared which shows the relationship between the thickness L1 of the first magneto-sensitive layers 14a and 14b and the determined write currents (Isw). In FIG. 11, the symbol ◯ indicates a write current flowing through the storage element 1a, and the symbol ● indicates a write current flowing through the storage element 1b.

It is confirmed from FIG. 11 that in the annular magnetic layer 4 of Type A, in a region where the thickness L1 is more than 50 nm, the balance between the write currents flowing through the storage elements 1a and 1b is largely lost, and there flows a large amount of write current as a whole. On the other hand, in a region where the thickness L1 is not more than 50 nm, it is confirmed that the current difference between the write currents flowing through the storage elements 1a and 1b tends to become gradually smaller to thereby cause the write currents to be gradually balanced (equal to each other), and that the write currents decrease sharply and almost linearly. Particularly when the thickness L1 is set at not more than 40 nm, it is confirmed that the write currents flowing through the storage elements 1a and 1b are substantially balanced, and decrease to 1.9 mA or less. Furthermore, if the thickness L1 is set at not more than 30 nm, it is confirmed that the write currents flowing through the storage elements 1a and 1b decrease to 1.6 mA or less.

(Experiment 2)

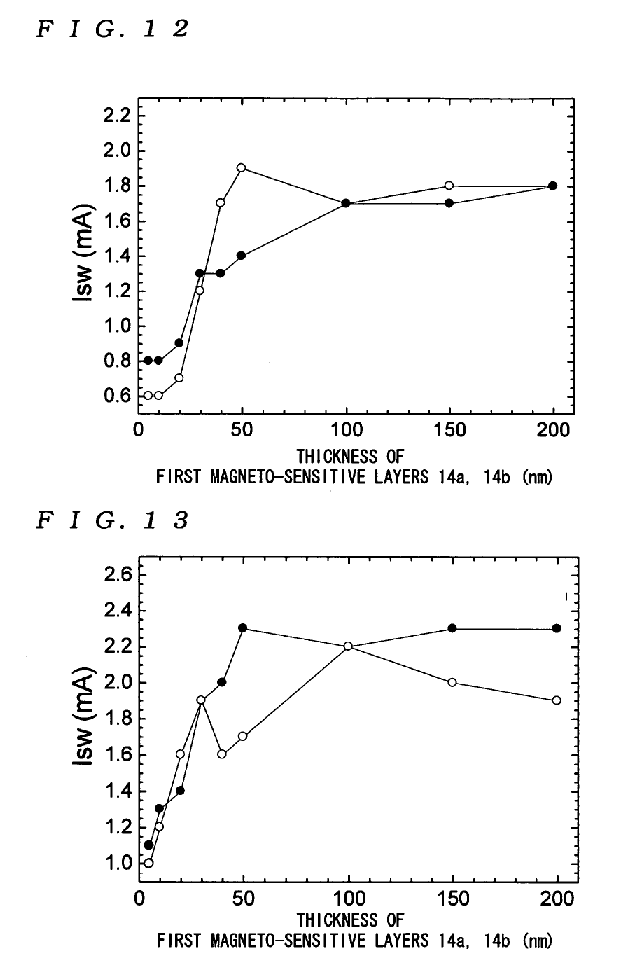

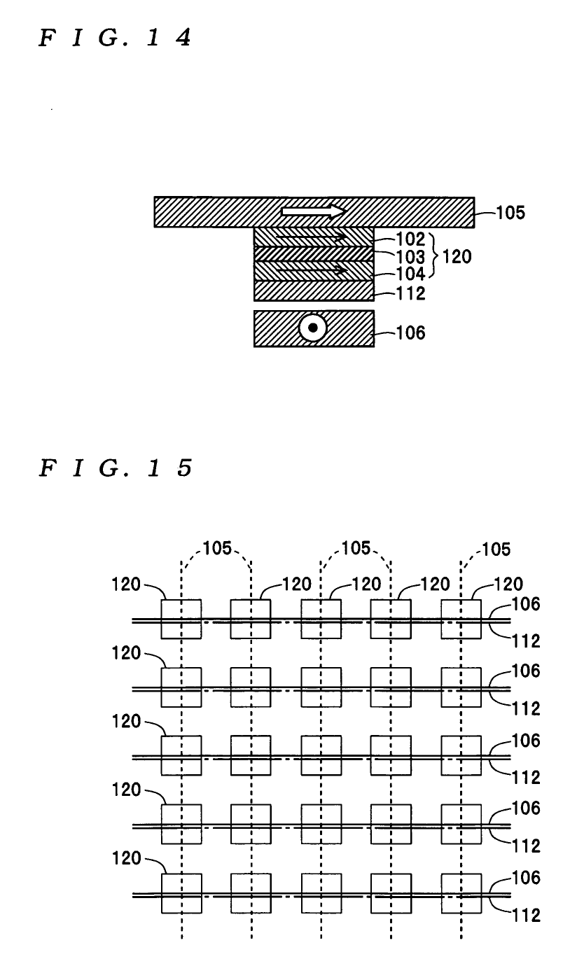

An annular magnetic layer 4 of Type B was assumed in which the sizes L2 to L7 of the portions shown in FIG. 9 were set at lengths indicated in the column of Type B shown in FIG. 10, and write currents (Isw) which flowed though the storage elements 1a and 1b of the annular magnetic layer 4 of Type B were determined by simulation, when the thickness L1 of the first magneto-sensitive layers 14a and 14b of the annular magnetic layer 4 of Type B was changed from 5 nm, to 10 nm, 20 nm, 30 nm, 40 nm, 50 nm, 100 nm, 150 nm, and 200 nm. Further, a characteristic diagram (FIG. 12) was prepared which shows the relationship between the thickness L1 of the first magneto-sensitive layers 14a and 14b and the determined write currents(Isw). In FIG. 12, the symbol ◯ indicates a write current flowing through the storage element 1a, and the symbol ● indicates a write current flowing through the storage element 1b.

It is confirmed from FIG. 12 that in the annular magnetic layer 4 of Type B, in a region where the thickness L1 is equal to or more than 100 nm, the write currents flowing through the storage elements 1a and 1b are relatively well balanced, but there flows a large amount of write current as a whole. Further, in a region where the thickness L1 is not less than 50 nm to less than 100 nm, the balance between the write currents flowing through the storage elements 1a and 1b is largely lost, and there still flows a large amount of write current as a whole. On the other hand, in a region where the thickness L1 is less than 50 nm, it is confirmed that the write currents flowing through the storage elements 1a and 1b decrease sharply. Particularly in a region where the thickness L1 is more than 20 nm to not more than 40 nm, it is confirmed that the current difference between the write currents flowing through the storage elements 1a and 1b becomes smaller, and the current values of the write currents also decrease to 1.7 mA or less. In this case, in a region where the thickness L1 is more than 20 nm to not more than 30 nm, it is confirmed that the current difference between the write currents flowing through the storage elements 1a and 1b becomes very small. On the other hand, in a region where the thickness L1 is not less than 5 nm to not more than 20 nm, it is confirmed that the current difference between the write currents flowing through the storage elements 1a and 1b becomes slightly larger, and the balance between the write currents is slightly lost, but the current values of the write currents are maintained at a very low level of 0.9 mA or less, whereby the write currents flowing through the whole memory cell 1 largely decrease.

(Experiment 3)

An annular magnetic layer 4 of Type C was assumed in which the sizes L2 to L7 of the portions shown in FIG. 9 were set at lengths indicated in the column of Type C shown in FIG. 10, and write currents (Isw) which flowed though the storage elements 1a and 1b of the annular magnetic layer 4 of Type C were determined by simulation, when the thickness L1 of the first magneto-sensitive layers 14a and 14b of the annular magnetic layer 4 of Type C was changed from 5 nm, to 10 nm, 20 nm, 30 nm, 40 nm, 50 nm, 100 nm, 150 nm, and 200 nm. Further, a characteristic diagram (FIG. 13) was prepared which shows the relationship between the thickness L1 of the first magneto-sensitive layers 14a and 14b and the determined write currents (Isw). In FIG. 13, the symbol ◯ indicates a write current flowing through the storage element 1a, and the symbol ● indicates a write current flowing through the storage element 1b.

It is confirmed from FIG. 13 that in the annular magnetic layer 4 of Type C, in a region where the thickness L1 is not less than 50 nm, the balance between the write currents flowing through the storage elements 1a and 1b is largely lost, and there flows a large amount of write current as a whole. On the other hand, in a region where the thickness L1 is more than 40 nm to less than 50 nm, it is confirmed that although the write currents flowing through the storage elements 1a and 1b slightly decrease, the current difference between the write currents flowing through the storage elements 1a and 1b is still large, and at the same time the balance between the write currents is largely lost. Further, in a region where the thickness L1 is equal to or less than 40 nm, it is confirmed that the current difference between the write currents flowing through the storage elements 1a and 1b becomes gradually smaller, and the write currents flowing through the storage elements 1a and 1b can be lowered to 2.0 mA or less. Particularly in a region where the thickness L1 is not more than 30 nm, it is confirmed that the write currents flowing through the storage elements 1a and 1b decrease sharply and almost linearly, and that the current difference between the write currents becomes almost zero to balance the write currents.

From the above-described experiments, it is confirmed that in the annular magnetic layer 4 of any type, if the thickness L1 of the first magneto-sensitive layers 14a and 14b is set at not less than 5 nm to not more than 40 nm, it is possible to reduce the write currents flowing through the storage elements la and 1b, while ensuring the balance between the write currents to some extent. Particularly when the thickness L1 is set at not more than 30 nm, it is confirmed that the current values of the write currents flowing through the storage elements 1a and 1b can be almost balanced, and it is possible to further reduce the write currents. Further, it is confirmed from the experiments that in the region where the thickness L1 of the first magneto-sensitive layers 14a and 14b is less than 50 nm, the write currents flowing through the storage elements 1a and 1b decrease almost uniformly as the thickness L1 of the first magneto-sensitive layers 14a and 14b becomes thinner. Therefore, although no further simulation was performed, it is considered that in the annular magnetic layer 4 of any type, until the thickness L1 is decreased to 0.5 nm, which is a limit of manufacturing the first magneto-sensitive layers 14a and 14b, it is possible to hold the current values of the write currents at a sufficiently low level, while ensuring the balance between the write currents to some extent.

### INDUSTRIAL APPLICABILITY

As described hereinabove, the memory cell and the magnetic memory device according to the present invention are comprised of an annular magnetic layer through which extends at least one conductor that generates a magnetic field, and a laminate configured so as to include: first magneto-sensitive layer, a magnetization direction of which is changed by the magnetic fields in the annular magnetic layer; and a magnetoresistive effect revealing body disposed on a surface of the first magneto-sensitive layer so that an electric current flows in a direction perpendicular to laminating surface of the laminate, wherein the first magneto-sensitive layer has a thickness set at not less than 0.5 nm to not more than 40 nm. This enables the first magneto-sensitive layer to secure a thickness of 0.5 nm or more, which makes it possible to stably manufacture the first magneto-sensitive layer as a magnetic film. As a result, it is possible to enhance the manufacturing yield. Further, since the thickness of the first magneto-sensitive layer is set at not more than 40 nm, a demagnetizing field due to the thickness of the first magneto-sensitive layer decreases, and therefore it is possible to reduce the write current required for inverting the magnetization direction of the first magneto-sensitive layer to efficiently change the magnetization direction of the first magneto-sensitive layer while ensuring the balance between the write currents flowing through the storage element to some extent. This makes it possible to realize a magnetic memory cell and a magnetic memory device, which are capable of changing the magnetization direction of the magneto-sensitive layer efficiently with a small amount of electric current.

### DESCRIPTION OF REFERENCE NUMERALS

1: memory cell
1a, 1b storage element
2a, 2b first magnetic layer
3a, 3b tunnel barrier layer
4, 4a, 4b annular magnetic layer
5a, 5b write bit line (a plurality of conductors)
6 write word line (a plurality of conductors)
8a, 8b second magneto-sensitive layer
12 read word line
13a, 13b read bit line
14a, 14b first magneto-sensitive layer
34 shared portion
M magnetic memory device
S20a, S20b TMR film (laminate)

1. A magnetic memory cell comprising an annular magnetic layer through which extends at least one conductor that generates a magnetic field, and a laminate configured so as to include: a first magneto-sensitive layer, a magnetization direction of which is changed by the magnetic field in the annular magnetic layer; and a magnetoresistive effect revealing body disposed on a surface of the first magneto-sensitive layer so that an electric current flows in a direction perpendicular to a laminating surface of the laminate,
wherein the first magneto-sensitive layer has a thickness set in a range of not less than 0.5 nm to not more than 40 nm.

2. A magnetic memory cell comprising a plurality of storage elements each having an annular magnetic layer through which extends at least one conductor that generates a magnetic field, and a laminate configured so as to include: a first magneto-sensitive layer, a magnetization direction of which is changed by the magnetic field in the annular magnetic layer; and a magnetoresistive effect revealing body disposed on a surface of the first magneto-sensitive layer so that an electric current flows in a direction perpendicular to a laminating surface of the laminate,
wherein the plurality of annular magnetic layers are configured so as to be arranged side by side such that directions of respective axes coincide with each other, and so as to share a predetermined portion of each with each other;
wherein the plurality of first magneto-sensitive layers are disposed on a same side with respect to a plane including the axes, and each have a thickness set in a range of not less than 0.5 nm to not more than 40 nm.

3. A magnetic memory cell according to claim 2, wherein the plurality of first magneto-sensitive layers are magnetized in respective directions antiparallel to each other by the magnetic fields.

4. A magnetic memory cell according to claim 1, wherein each first magneto-sensitive layer has a thickness set in a range of not less than 0.5 nm to not more than 30 nm.

5. A magnetic memory cell according to claim 1, wherein a plurality of the conductors extend through the plurality of annular magnetic layers, and the plurality of the conductors extend in parallel to each other in a region where the plurality of the conductors extend through the plurality of annular magnetic layers.

6. A magnetic memory cell according to claim 1, wherein the laminate comprises a second magneto-sensitive layer which can be magnetically exchange-coupled with each first magneto-sensitive layer.

7. A magnetic memory cell according to claim 6, wherein the laminate comprises a non-magnetic layer, a first magnetic layer with a fixed magnetization direction deposited on one surface side of the non-magnetic layer, and a second magnetic layer deposited on the other surface side of the non-magnetic layer and functioning as the second magneto-sensitive layer,
wherein information can be detected based on the electric current flowing through the laminate.

8. A magnetic memory cell according to claim 7, wherein the first magnetic layer is formed using a material having a larger coercive force than the second magnetic layer.

9. A magnetic memory device including a magnetic memory cell according to claim 1,
write lines as the plurality of the conductors, and
read lines that supply the electric current to the laminate.

10. A magnetic memory cell according to claim 2, wherein each first magneto-sensitive layer has a thickness set in a range of not less than 0.5 nm to not more than 30 nm.

11. A magnetic memory cell according to claim 2, wherein a plurality of the conductors extend through the plurality of annular magnetic layers, and the plurality of the conductors extend in parallel to each other in a region where the plurality of the conductors extend through the plurality of annular magnetic layers.

12. A magnetic memory cell according to claim 2, wherein the laminate comprises a second magneto-sensitive layer which can be magnetically exchange-coupled with each first magneto-sensitive layer.

13. A magnetic memory cell according to claim 12, wherein the laminate comprises a non-magnetic layer, a first magnetic layer with a fixed magnetization direction deposited on one surface side of the non-magnetic layer, and a second magnetic layer deposited on the other surface side of the non-magnetic layer and functioning as the second magneto-sensitive layer,
wherein information can be detected based on the electric current flowing through the laminate.

14. A magnetic memory cell according to claim 13, wherein the first magnetic layer is formed using a material having a larger coercive force than the second magnetic layer.

15. A magnetic memory device including a magnetic memory cell according to claim 2,
write lines as the plurality of the conductors, and
read lines that supply the electric current to the laminate.
